(19) United States
(12) Patent Application Publication
(10) Pub. No.: US 2014/0042473 A1
(43) Pub. Date: Feb. 13, 2014

(54) VERTICAL LIGHT EMITTING DIODE AND MANUFACTURING METHOD AND APPLICATION THEREOF

(71) Applicant: Chien-MIn Sung, Tansui (TW)

(72) Inventor: Chien-MIn Sung, Tansui (TW)

(21) Appl. No.: 13/834,320

(22) Filed: Mar. 15, 2013

Related U.S. Application Data
(63) Continuation-in-part of application No. 13/412,493, filed on Mar. 5, 2012.
Application No. 13/412,493 is a continuation-in-part of application No. 13/284,900, filed on Oct. 29, 2011.
Application No. 13/284,900 is a continuation-in-part of application No. 13/239,189, filed on Sep. 21, 2011, now Pat. No. 8,531,026.
Application No. 13/239,189 is a continuation-in-part of application No. 13/344,527, filed on Jan. 5, 2012, now abandoned.
Application No. 13/344,527 is a continuation-in-part of application No. 13/747,388, filed on Jan. 22, 2013, now abandoned.
(60) Provisional application No. 61/408,447, filed on Oct. 29, 2010.
(60) Provisional application No. 61/384,976, filed on Sep. 21, 2010.
(60) Provisional application No. 61/468,917, filed on Mar. 29, 2011.

(30) Foreign Application Priority Data
Jan. 5, 2011 (TW) 100100357
Jan. 19, 2012 (TW) 101102135

(51) Int. Cl. H01L 33/60; H01L 33/00

(52) U.S. Cl. CPC H01L 33/60; H01L 33/005
USPC 257/98; 257/99; 438/38

(57) ABSTRACT

A vertical light emitting diode (LED) is disclosed, which includes a conductive substrate; a conductive diamond-like carbon (DLC) layer located on the conductive substrate; a first passivation layer disposed on the conductive DLC layer and formed with a first opening; a first electrode located on the conductive DLC layer and in the first opening of the first passivation layer; a semiconductor epitaxial multilayer structure disposed on the first electrode; a second passivation layer disposed on the first passivation layer and covering the lateral surface of the semiconductor epitaxial multilayer structure, wherein a second opening is formed in the second passivation layer to expose the surface of the semiconductor epitaxial multilayer structure; and a second electrode located on the semiconductor epitaxial multilayer structure and in the second opening of the second passivation layer. A method for manufacturing the vertical LED mentioned above is also disclosed.

### PRIORITY INFORMATION

This application is a continuation-in-part of U.S. patent application Ser. No. 13/412,493, filed on Mar. 5, 2012, which is a continuation-in-part of U.S. patent application Ser. No. 13/284,900, filed on Oct. 29, 2011, which claims the benefit of U.S. Provisional Patent Application Ser. No. 61/408,447, filed on Oct. 29, 2010, and which is a continuation-in-part of U.S. patent application Ser. No. 13/239,189, filed on Sep. 21, 2011, which claims the benefit of United States Provisional Patent Application Ser. Nos. 61/384,976 and 61/468,917, filed on Sep. 21, 2010 and Mar. 29, 2011 respectively. This application is also a continuation-in-part of U.S. patent application Ser. No. 13/344,527, filed on Jan. 5, 2012, which claims the benefit of the Taiwan Patent Application Serial Number 100100357, filed on Jan. 5, 2011. This application is also a continuation-in-part of U.S. patent application Ser. No. 13/747,388, filed on Jan. 22, 2013, which claims the benefit and priority of Taiwan Patent Application TW 101102135 and filed on Jan. 19, 2012. Each of the aforementioned patent applications is incorporated herein by reference.

### FIELD OF THE INVENTION

The present invention relates to a vertical light emitting diode and manufacturing method and application thereof. More particularly, the present invention relates to a vertical light emitting diode featuring low current leakage and reversed bias and manufacturing method and a chip on board using thereof.

### BACKGROUND OF THE INVENTION

Since the 1960s, light emitting diodes (LEDs) have progressively replaced traditional lighting lamps, indicator lamps of electrical devices or other light sources due to their benefits such as low power consumption and long duration time. Moreover, the development of multicolor LEDs with high brightness has contributed to their application in large outdoor display boards or traffic light.

In recent years, due to the vigorous development of the electronics industry, the increasing demand for electronic products, electronic products into a multifunction and efficient development direction, and also began to light-emitting diode chips used in various electronic products. Particularly, the types of portable electronic products increasingly large, the size and weight of electronic products are getting smaller and smaller, circuit carrier board required volume will be smaller.

A manufacturing process of a conventional vertical LED is referred in FIGS. 1A to 1H. First, as shown in FIG. 1A, a temporary substrate 11 is deposited and then, as shown in FIG. 1B, a secondary semiconductor epitaxial layer 123, an active interlayer 122 and a first semiconductor epitaxial layer 121 are sequentially deposited. After that, the secondary semiconductor epitaxial layer 123, the active interlayer 122 and the first semiconductor epitaxial layer 121 are patterned by etching or other methods for forming a plurality of semiconductor epitaxial multilayer structures 12.

Then, as shown in FIG. 1C, a reflective layer 142 is formed on the surface 121 of the semiconductor epitaxial multilayer structures 12. As shown in FIG. 1D, a passivation layer 17 would cover the sidewall of the semiconductor epitaxial multilayer structures 12 and the surface of the temporary substrate 11, as well as, the surface of the reflective layer 142 would be exposed. After that, as shown in FIG. 1E, a first electrode 14 is formed on the passivation layer 17 and the surface of the reflective layer 142. As shown in FIG. 1F, a conductive diamond-like carbon (DLC) layer 15 is formed on the surface of the first electrode 14. Then, as shown in FIG. 1G, the temporary substrate 11 is removed by using laser lift-off technique. Finally, a second electrode 18 is formed on the surface of the secondary semiconductor epitaxial layer 123 of the semiconductor epitaxial multilayer structures 12.

However, as the conventional process described above, when the temporary substrate 11 is removed by using laser lift-off technique, the passivation layer 17 could be easily damaged. And such could then lead to the passivation layer 17 not become not able to protect and isolate the first electrode 14, and raise issues such as leakage or short circuit.

Accordingly, if the problem described above could be resolved, it would further improve the yield of the vertical LED and ultimately improve the development of the overall electronics industry.

### BRIEF DESCRIPTION OF THE DRAWINGS

FIGS. 1A to 1H show a process of fabricating a conventional vertical light emitting diode;

FIGS. 2A to 2H show a process of fabricating a vertical light emitting diode according to Example 1 of the present invention;

FIG. 3 shows a schematic view of a chip-on-board package according to Example 2 of the present invention;

List of Reference Numerals

| | |
|---|---|
| temporary substrate | 11, 21 |
| the second semiconductor epitaxial layer | 123, 223 |
| the active interlayer | 122, 222 |
| the first semiconductor epitaxial layer | 121, 221 |
| the semiconductor epitaxial multilayer structure | 12, 22 |
| the first passivation layer | 23 |
| the first opening | 231 |
| the reflective layer | 142, 242 |
| the first electrode layer | 241 |
| the first electrode | 14, 24 |
| the conductive DLC layer | 15, 25 |
| the conductive substrate | 26 |
| the passivation layer | 17 |
| the secondary passivation layer | 27 |
| the second opening | 271 |
| the secondary electrode | 18, 28 |
| the print circuit board | 3 |
| the insulated layer | 31 |
| the print circuit substrate | 30 |

### DESCRIPTION OF THE INVENTION

One aspect of the present invention is to provide a vertical light emitting diode, wherein the effect of protecting the first electrode could be achieved by disposing a first passivation layer during the manufacturing process. At the same time, it could avoid the problem caused by the damage of the secondary passivation layer such as the leakage of the first electrode or short circuit.

To achieve the object, one aspect of the present invention provides a vertical light emitting diode, comprising: a conductive substrate; a conductive diamond-like carbon (DLC) layer located on the conductive substrate; a first passivation layer disposed on the conductive DLC layer and formed with a first opening; a first electrode located on the conductive DLC layer and in the first opening of the first passivation layer; a semiconductor epitaxial multilayer structure disposed on the first electrode; a second passivation layer disposed on the first passivation layer and covering the lateral surface of the semiconductor epitaxial multilayer structure, wherein a second opening is formed in the second passivation layer to expose the surface of the semiconductor epitaxial multilayer structure; and a second electrode located on the semiconductor epitaxial multilayer structure and in the second opening of the second passivation layer.

As the vertical light emitting diode of the present invention described above, the first electrode includes a first electrode layer and a reflective layer, wherein the reflective layer is interposed between the first electrode layer and the semiconductor epitaxial multilayer structure.

In the vertical light emitting diode of the present invention described above, the semiconductor epitaxial multilayer structure may include a first semiconductor epitaxial layer, an active interlayer and a second semiconductor epitaxial layer, wherein the active interlayer is interposed between the first semiconductor epitaxial layer and the second semiconductor epitaxial layer. In the present invention, the active interlayer could be a multiple quantum well layer for improving the photoelectric conversion efficiency of the light emitting diode.

As the vertical light emitting diode of the present invention described above, the first electrode may include a first electrode layer and a reflective layer, wherein the reflective layer is interposed between the first electrode layer and the semiconductor epitaxial multilayer structure. In the present invention, the material of the reflective layer is not particularly limited, for example, it may be aluminum, silver, nickel (Ni), cobalt (Co), palladium (Pd), platinum (Pt), gold (Au), zinc (Zn), tin (Sn), antimony (Sb), lead (Pb), copper (Cu), copper silver (CuAg), nickel silver (NiAg), an alloy thereof, or a mixture thereof. In other words, the reflective layer may be a multilayered metal structure. In addition to achieve the reflective effect, it may also achieve the effect of forming ohmic contact.

As the vertical light emitting diode of the present invention described above, the first semiconductor epitaxial layer and the first electrode layer may each be P type, and the second semiconductor epitaxial layer and the second electrode layer may each be N type.

As the vertical light emitting diode of the present invention described above, the conductive DLC layer may be a multilayer structure composed by a conductive material and a conductive DLC, a DLC layer including the conductive material, a graphitizing DLC layer or a combination thereof, wherein the conductive material is at least one selected from the group consisting of indium tin oxide (ITO), aluminum zinc oxide (AZO), zinc oxide (ZnO), graphene, titanium (Ti), aluminum (Al), chromium (Cr), nickel (Ni), platinum (Pt), molybdenum (Mo), tungsten (W), silver (Ag), platinum (Pt), and gold (Au).

As the vertical light emitting diode of the present invention described above, the conductive substrate is composed of a metal, a ceramic including the conductive material or a diamond including the conductive material.

As the vertical light emitting diode of the present invention described above, the material of the first passivation layer is not particularly limited, as long as it can protect the first electrode 24 from being damaged by subsequent etching solution or any other solution. The material of the first passivation layer is not particularly limited, as long as it is able to protect the side of the semiconductor epitaxial multilayer structure from being influenced by any undesirable. The first passivation layer and the second passivation layer may each be independently composed of silicon dioxide, silicon nitride, aluminum nitride, insulated DLC or a combination thereof.

The other object of the present invention is to provide a method of manufacturing a vertical light emitting diode, wherein a first passivation layer and a first electrode are formed before the patterning steps are performed to form a plurality of semiconductor epitaxial multilayer structure. The first passivation layer may protect the first electrode from being damaged by the etching solution during the manufacturing process. After that, the temporary substrate is removed by using laser lift-off technique. Then, a plurality of semiconductor epitaxial multilayer structure is formed by patterning and the sidewall of the semiconductor epitaxial multilayer structure may be covered by a secondary passivation layer. Therefore, it may avoid the prior art problem caused by the damage of the secondary passivation layer such as leakage or short circuit.

To achieve the object, another aspect of the present invention provides a method of manufacturing a vertical light emitting diode, comprising: providing a temporary substrate and forming a semiconductor epitaxial multilayer structure, a first electrode and a first passivation layer on the temporary substrate, wherein the semiconductor epitaxial multilayer structure is disposed on the temporary substrate, the first passivation layer and the first electrode are disposed on the semiconductor epitaxial multilayer structure, the first passivation layer is patterned into a first opening, and the first electrode is embedded in the first opening of the first passivation layer; forming a conductive DLC layer on the first passivation layer and the first electrode; patterning the semiconductor epitaxial multilayer structure to expose the first passivation layer; forming a second passivation layer on the patterned semiconductor epitaxial multilayer structure and the first passivation layer, wherein the second passivation layer is disposed a plurality of second openings to expose the patterned semiconductor epitaxial multilayer structure; and forming a second electrode in the second openings of the second passivation layer and on the patterned semiconductor epitaxial multilayer structure.

In the conventional technique of forming a vertical LED, mostly, a plurality of semiconductor epitaxial multilayer structure is first formed on a temporary substrate by a patterning process. However, such method would provide to form a secondary passivation layer for covering the sidewall of the semiconductor epitaxial multilayer structure. Therefore, a part of the secondary passivation layer would contact with the temporary substrate, so that the secondary passivation layer is damaged during removing the temporary substrate by laser lift-off technique. Thus, the first electrode covered by the secondary passivation layer is exposed and result in leakage or short circuit of the overall structure.

On the contrary, as the method of the present invention of manufacturing a vertical light emitting diode described above, a first passivation layer and a first electrode are formed before a plurality of semiconductor epitaxial multilayer structure is formed by patterning. The first passivation layer may be used to protect the surrounding of the first electrode in order to prevent it from being damaged by etching steps during the manufacturing process. Even if the temporary substrate is subsequently removed by using laser lift-off technique, the secondary passivation layer is not yet formed, thus it will not be damaged. Subsequently, a plurality of semiconductor epitaxial multilayer structure is formed by pattering, and then the side of the semiconductor epitaxial multilayer structure may be covered by a secondary passivation layer. Therefore, it may avoid the leakage or short circuit that easily occur in the prior art.

As the method of the present invention of manufacturing a vertical light emitting diode described above, the first passivation layer is formed on the semiconductor epitaxial multilayer structure and then patterned to form the first opening, after that, on the semiconductor epitaxial multilayer structure, forming the first electrode in the first opening of the first passivation layer.

As the method of the present invention of manufacturing a vertical light emitting diode described above, before forming the second passivation layer, further comprising: roughening the patterned semiconductor epitaxial multilayer structure.

As the method of the present invention of manufacturing a vertical light emitting diode described above, the first electrode includes a first electrode layer and a reflective layer, wherein the reflective layer is interposed between the first electrode layer and the semiconductor epitaxial multilayer structure.

As the method of the present invention of manufacturing a vertical light emitting diode described above, the semiconductor epitaxial multilayer structure includes a first semiconductor epitaxial layer, an active interlayer and a second semiconductor epitaxial layer, wherein the active interlayer is interposed between the first semiconductor epitaxial layer and the second semiconductor epitaxial layer. The active interlayer could be a multiple quantum well layer for improving the photoelectric conversion efficiency of the light emitting diode.

As the method of the present invention of manufacturing a vertical light emitting diode described above, the first semiconductor epitaxial layer and the first electrode layer are each P type, and the second semiconductor epitaxial layer and the second electrode layer are each N type.

As the method of the present invention of manufacturing a vertical light emitting diode described above, the first electrode includes a first electrode layer and a reflective layer, wherein the reflective layer is interposed between the first electrode layer and the semiconductor epitaxial multilayer structure. The material of the reflective layer is not particularly limited, for example, it may be aluminum, silver, nickel (Ni), cobalt (Co), palladium (Pd), platinum (Pt), gold (Au), zinc (Zn), tin (Sn), antimony (Sb), lead (Pb), copper (Cu), copper silver (CuAg), nickel silver (NiAg), an alloy thereof, or a mixture thereof. In other words, the reflective layer may be a multilayered metal structure. In addition to achieve the reflective effect, it may also achieve the effect of forming ohmic contact.

As the method of the present invention of manufacturing a vertical light emitting diode described above, the conductive DLC layer may be a multilayer structure composed by a conductive material and a conductive DLC, a DLC layer including the conductive material, a graphitizing DLC layer or a combination thereof, wherein the conductive material is at least one selected from the group consisting of indium tin oxide (ITO), aluminum zinc oxide (AZO), zinc oxide (ZnO), graphene, titanium (Ti), aluminum (Al), chromium (Cr), nickel (Ni), platinum (Pt), molybdenum (Mo), tungsten (W), silver (Ag), platinum (Pt), and gold (Au).

As the method of the present invention for fabricating a vertical light emitting diode described above, the conductive substrate is composed of a metal, a ceramic including the conductive material or a diamond including the conductive material. In addition, the first passivation layer and the second passivation layer may each be independently composed of silicon dioxide, silicon nitride, aluminum nitride, insulated DLC or a combination thereof.

In addition, still another object of the present invention is to provide a chip on board (COB), wherein the vertical LED of the present invention containing conductive DLC described above is electrically connected to a print circuit board by flip chip or wire bonding. Therefore, the thermal expansion stress of each layer of the LED could be buffered by the DLC layer disposed in the structure, so that making the overall of the COB has a better heat dissipating efficiency, luminescence efficiency and life span.

To achieve the object, still another aspect of the present invention provides a chip on board (COB), comprising: a print circuit board; and the vertical LED of the present invention containing conductive DLC described above where is electrically connected to the print circuit board by the first electrode and the secondary electrode.

As the COB of the present invention described above, the print circuit board may include an insulated layer and a print circuit substrate, the insulated layer may be a diamond-like carbon, an aluminum oxide, a ceramic and an epoxy resin including diamond. The print circuit substrate may be a metal plate, a ceramic plate or a silicon substrate. In addition, the print circuit board may also selectively include a DLC layer for improving heat dissipating efficiency.

### EXAMPLES

The following examples are illustrative of various embodiments of the present invention. Other advantages and effects of the invention will become more apparent from the description of the present invention. Other various aspects also may be practiced or applied in the invention, and various modifications and variations can be made without departing from the spirit of the invention based on various concepts and applications.

### Example 1

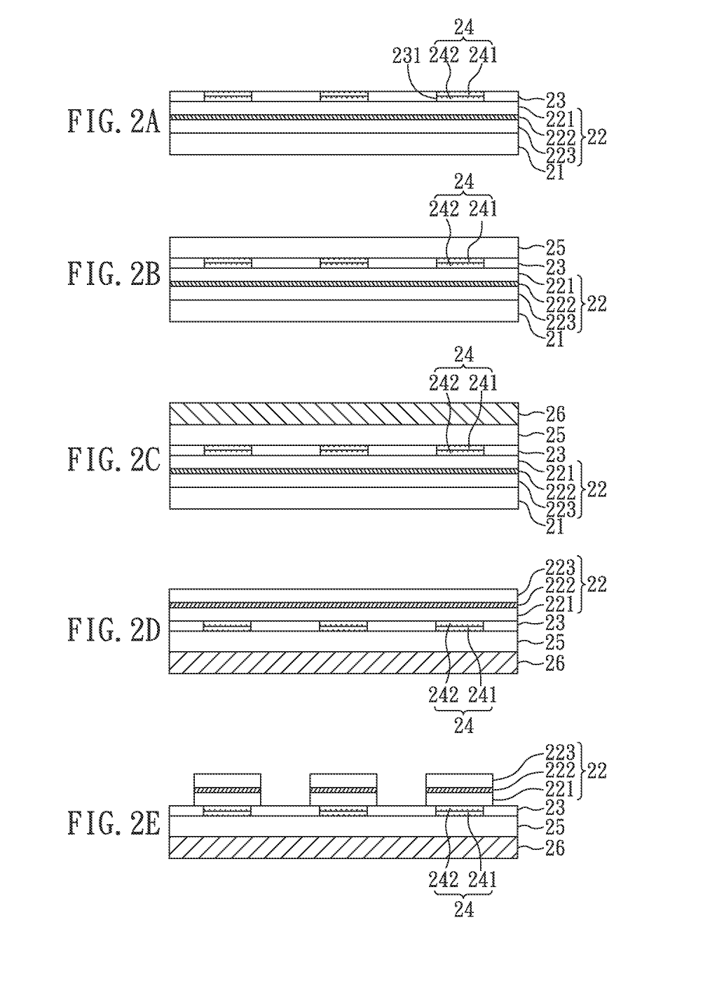

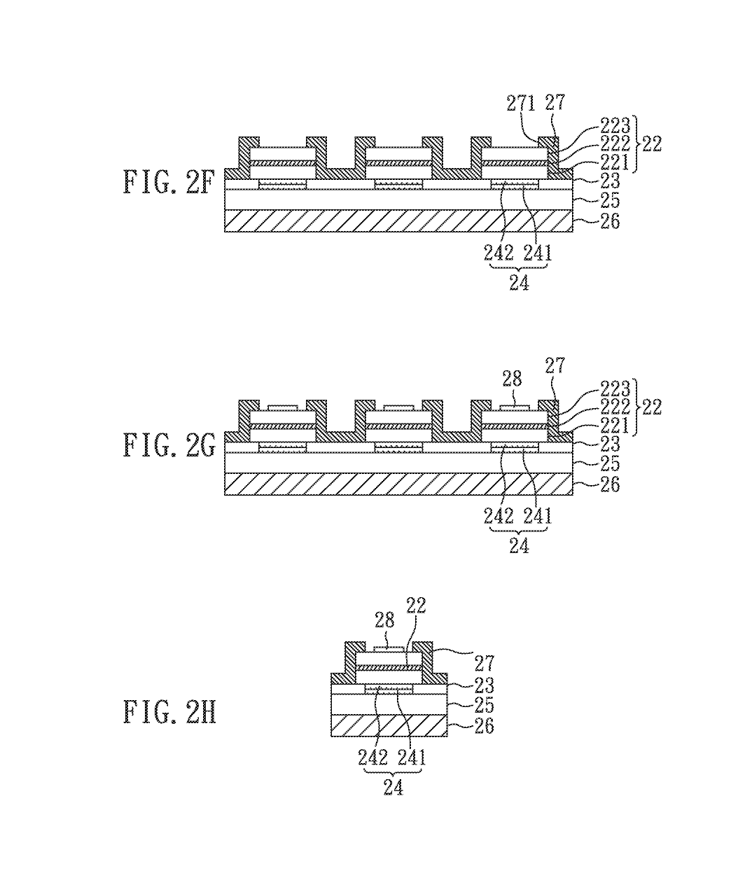

FIGS. 2A to 2H showing a process of fabricating a vertical light emitting diode according to the present invention will now be discussed.

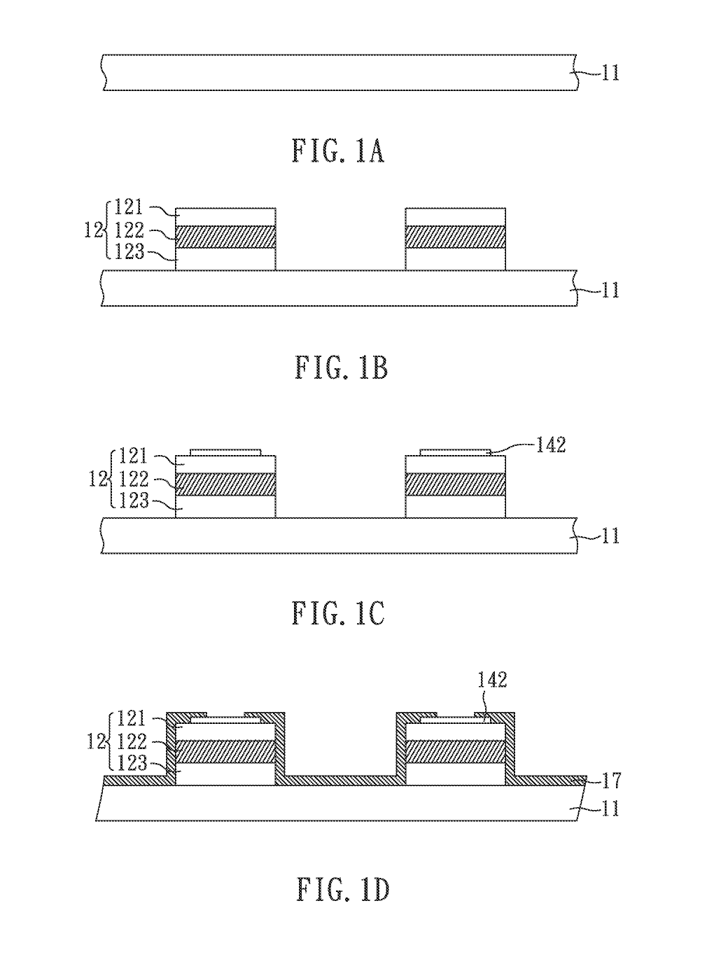

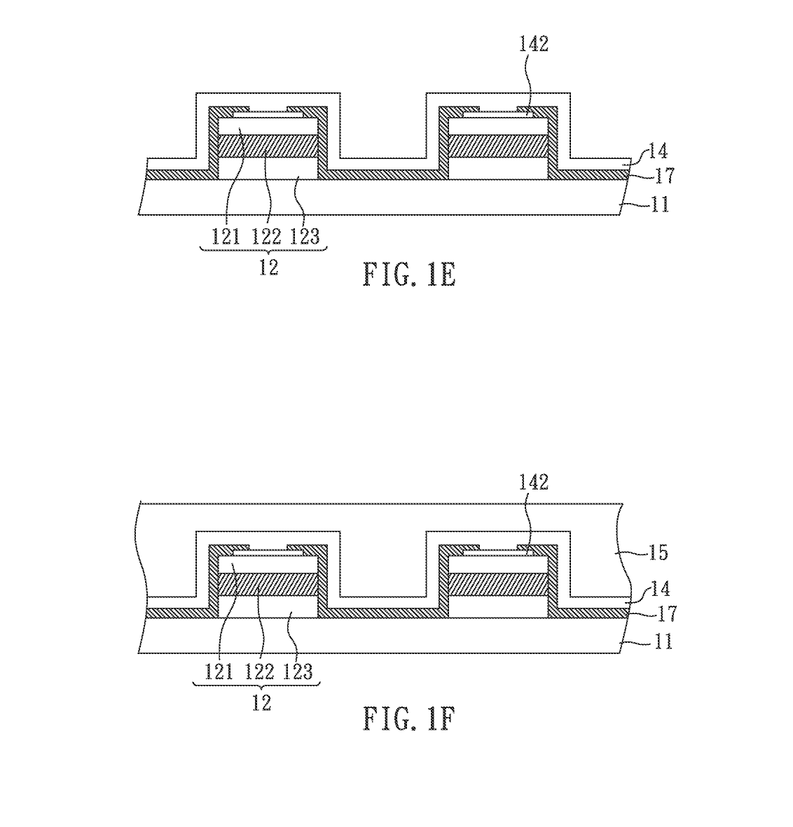

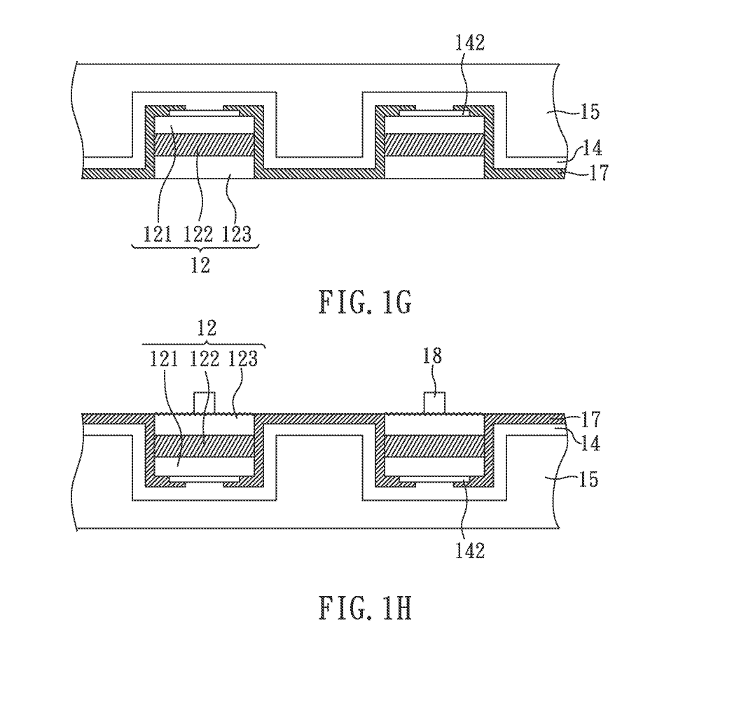

First, as shown in FIG. 1A, a temporary substrate 21 is provided and a semiconductor epitaxial multilayer structure 22, a first electrode 24 and a first passivation layer 23 are subsequently formed on the temporary substrate 21, wherein the semiconductor epitaxial multilayer structure 22 is disposed on the surface of the temporary substrate 21, the first passivation layer 23 and the first electrode 24 are disposed on the surface of the semiconductor epitaxial multilayer structure 22, the first passivation layer is patterned into a plurality of first opening 231, and the first electrode 24 is embedded in the first opening 231 of the first passivation layer 23. The material of the temporary substrate 21 may be, for example, sapphire.

The semiconductor epitaxial multilayer structure 22 may include an active interlayer 222 and a second semiconductor epitaxial layer 223, wherein the first semiconductor epitaxial layer 221, the active interlayer 222 and the second semiconductor epitaxial layer 223 are laminated, and the active interlayer 222 is interposed between the first semiconductor epitaxial layer 221 and the second semiconductor epitaxial layer and the second semiconductor epitaxial layer 223 is disposed on the surface of the temporary substrate 21. In the present example, the first semiconductor epitaxial layer 221 is N type, and the secondary semiconductor epitaxial layer 223 is P type, thus corresponding electrodes are subsequently formed to independently connect thereof. It means that the first electrode 24 that is connected to the first semiconductor epitaxial layer 221 is N type, and the secondary electrode (described below) that is connected to the secondary semiconductor epitaxial layer 223 is P type. The material of the semiconductor epitaxial multilayer structure 22 is gallium nitride (GaN), but the material been appropriate to the semiconductor epitaxial multilayer structure of the present invention is not limited thereof. Another commonly used material in the art could also be selected. In addition, the active interlayer could be a multiple quantum well layer for improving the photoelectric conversion efficiency of the light emitting diode.

The first electrode 24 may include a first electrode layer 241 and a reflective layer 242, wherein the reflective layer 242 is interposed between the first electrode layer 241 and the first semiconductor epitaxial layer 221. In the present example, the material of the reflective layer may be indium tin oxide (ITO), aluminum zinc oxide (AZO), zinc oxide (ZnO), grapheme, aluminum, silver, nickel (Ni), cobalt (Co), palladium (Pd), platinum (Pt), gold (Au), zinc (Zn), tin (Sn), antimony (Sb), lead (Pb), copper (Cu), copper silver (CuAg), nickel silver (NiAg), an alloy thereof, or a mixture thereof. CuAg and NiAg described above indicate eutectic metal. In addition to its ability to achieve the reflective effect, it may also achieve the effect of forming ohmic contact. For reflective layer 242, the skilled person in the art would clearly know the reflective layer could be selectively disposed. In other words, if the skilled person in the art does not intent to dispose the reflective layer, the process described above could bypass the forming step of the reflective layer 242.

The sequence of the formation steps of the first passivation layer 23 and the first electrode 24 is not particularly limited. First, the first passivation layer 23 is formed on the semiconductor epitaxial multilayer structure 22, and then the first passivation layer 23 is patterned to form a plurality of first opening 231, after that, the first electrode 24 is formed in the first opening 231 that is exposed on the semiconductor epitaxial multilayer structure 22. Otherwise, the first electrode 24 is formed on the semiconductor epitaxial multilayer structure 22 and patterned to form a plurality of blocks, and then the first passivation layer 23 is formed on the surface of the semiconductor epitaxial multilayer structure 22 and the passivation layer 23 is exposed on the surface of the first electrode 24. The material of the first passivation layer 23 is not particularly limited, as long as it can be able to protect the first electrode 24 from being damaged by etching solution or any other solution. For example, it may be silicon dioxide, silicon nitride, aluminum nitride, insulated DLC or a combination thereof.

Then, as shown in FIG. 2B, a conductive DLC layer 25 is formed on the surface of the first passivation layer 23 and the first electrode 24. The conductive DLC layer 25 may be a multilayer structure composed by a conductive material and a conductive DLC, a DLC layer including the conductive material, a graphitizing DLC layer or a combination thereof, wherein the conductive material is at least one selected from the group consisting of indium tin oxide (ITO), aluminum zinc oxide (AZO), zinc oxide (ZnO), graphene, titanium (Ti), aluminum (Al), chromium (Cr), nickel (Ni), platinum (Pt), molybdenum (Mo), tungsten (W), silver (Ag), platinum (Pt), and gold (Au). In otherwords, the conductive material may be composed by the alloy or the mixture thereof. Because DLC has a better coefficient of thermal expansion (CTE), the conductive DLC layer 25 could improve radiation while operating the LED. In the present example, the multilayer composite structure of Ti layer or Ti-Wo layer/conductive DLC layer is used to be the conductive DLC layer 25 that could be formed by using a cathodic arc multi-targets and cluster sputter.

Then, as shown in FIG. 2C, a conductive substrate 26 is formed on the surface of the conductive DLC layer 25. The material of the conductive substrate 26 is not particularly limited, as long as it is able to achieve the conductive effect, such as a metal, a ceramic including the conductive material or a diamond including the conductive material. If the material is a metal such as Cu, Ni—Cu, Ni, or a mixture such as diamond-Cu or diamond-Ni, it could be formed by using general metal plating. After that, as shown in FIG. 2D, the temporary substrate 21 is removed by using laser lift-off technique.

As shown in FIG. 2E, the semiconductor epitaxial multilayer structure 22 is patterned to form a plurality of blocks, thus the first passivation layer 23 is exposed, for example, it could be achieved by using inductive coupled plasma (IPC). Then, as shown in FIG. 2F, a secondary passivation layer 27 is formed on the patterned semiconductor epitaxial multilayer structure 22 and the first passivation layer 23, wherein the secondary passivation layer 27 covered with the side of the semiconductor epitaxial multilayer structure 22 and the surface of the first passivation layer 23, and the secondary passivation layer 27 disposes a plurality of secondary opening 271 to expose the surface of the semiconductor epitaxial multilayer structure 22. The material of the secondary passivation layer 27 is not particularly limited, as long as it can protect the semiconductor epitaxial multilayer structure 22 from being damaged, for example, it can be silicon dioxide, silicon nitride, aluminum nitride, insulated DLC or a combination thereof and can be formed by using plasma-enhanced chemical vapour deposition (PECVD). Before continuing following steps, the surface of the patterned semiconductor epitaxial multilayer structure 22 can first be roughened, for example, a wet etching can be applied to improve the luminous efficiency of the LED. The step can be optionally executed according to the needs.

Then, as shown in FIG. 2G, a secondary electrode 28 is formed in the secondary opening 271 of the secondary passivation layer 27 and on the patterned semiconductor epitaxial multilayer structure 22. The material of the secondary electrode 28 can use the electrode material in the art or can be similar to the material of the first electrode 24, for example, it can be indium tin oxide (ITO), aluminum zinc oxide (AZO), zinc oxide (ZnO), graphene, titanium (Ti), aluminum (Al), chromium (Cr), nickel (Ni), platinum (Pt), molybdenum (Mo), tungsten (W), silver (Ag), platinum (Pt), gold (Au), and a combination thereof or an alloy.

Finally, as shown in FIG. 2H, a single LED is separated by cutting, thus the vertical LED of the present invention is obtained comprising: a conductive substrate 26; a conductive diamond-like carbon (DLC) layer 25 located on the conductive substrate 26; a first passivation layer 23 disposed on the conductive DLC layer 25 and formed with a first opening 231; a first electrode 24 located on the conductive DLC layer 25 and in the first opening 231 of the first passivation layer 23, wherein the first electrode 24 includes a first electrode layer 241 and a reflective layer 242; a semiconductor epitaxial multilayer structure 22 disposed on the first electrode 24, wherein the semiconductor epitaxial multilayer structure 22 includes a first semiconductor epitaxial layer 221, an active interlayer 222 and a second semiconductor epitaxial layer 223, the active interlayer 222 is interposed between the first semiconductor epitaxial layer 221 and the second semiconductor epitaxial layer 223, and, the reflective layer 242 of the first electrode 24 is interposed between the first electrode layer 241 and the semiconductor epitaxial multilayer structure 22; a second passivation layer 27 disposed on the first passivation layer 23 and covering the lateral surface of the semiconductor epitaxial multilayer structure 22, and disposed a second opening 271 to expose the surface of the semiconductor epitaxial multilayer structure 22; and a second electrode 28 located on the semiconductor epitaxial multilayer structure 22 and in the second opening 271 of the second passivation layer 27.

### Example 2

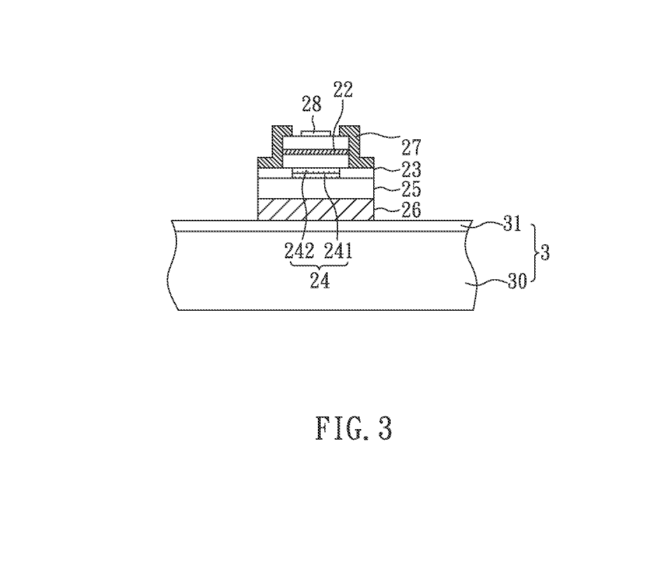

Referring FIG. 3, a schematic view showing a chip-on-board package according to the example of the present invention is presented.

As shown in FIG. 3, a chip on board (COB) comprises: a print circuit board 3; and the vertical LED according to the example 1 that is electrically connected to in the print circuit board 3 by the first electrode 24 and the secondary electrode 28, wherein the print circuit board 3 may include an insulated layer 31, a print circuit substrate 30, and a circuit (not shown). The insulated layer 31 may be a diamond-like carbon, an aluminum oxide, a ceramic and an epoxy resin including diamond. The print circuit substrate 30 may be a metal plate, a ceramic plate or a silicon substrate.

As the COB of the present invention described above, the electrical connection between the first electrode 24, the secondary electrode 28 and the print circuit board 3 could be achieved by using the ordinary method in the art such as wire bonding.

Accordingly, as the COB of the present invention described above, the secondary passivation layer and the first passivation layer of the LED could protect the first electrode and the lateral surface of the semiconductor epitaxial multilayer structure at the same time. Thus, it may avoid leakage or short circuit, so that the COB has a better heat dissipating efficiency, luminous efficiency and life span.

Accordingly, as the vertical LED of the present invention described above, the structure is safe without defect. Thus it can avoid the problem such as the leakage or short circuit caused by the damage of the structure of the LED, so that the safety of the user and the luminous efficiency and life span of the LED could be improved.

Although the present invention has been explained in relation to its preferred embodiment, it is to be understood that many other possible modifications and variations can be made without departing from the spirit and scope of the invention as hereinafter claimed.

What is claimed is:

1. A vertical light emitting diode, comprising:
a conductive substrate;
a conductive diamond-like carbon (DLC) layer located on the conductive substrate;
a first passivation layer disposed on the conductive DLC layer and formed with a first opening;
a first electrode located on the conductive DLC layer and in the first opening of the first passivation layer;
a semiconductor epitaxial multilayer structure disposed on the first electrode;
a second passivation layer disposed on the first passivation layer and covering the lateral surface of the semiconductor epitaxial multilayer structure, wherein a second opening is formed in the second passivation layer to expose the surface of the semiconductor epitaxial multilayer structure; and
a second electrode located on the semiconductor epitaxial multilayer structure and in the second opening of the second passivation layer.

2. The vertical light emitting diode as claimed in claim 1, wherein the first electrode includes a first electrode layer and a reflective layer, wherein the reflective layer is interposed between the first electrode layer and the semiconductor epitaxial multilayer structure.

3. The vertical light emitting diode as claimed in claim 1, wherein the semiconductor epitaxial multilayer structure includes a first semiconductor epitaxial layer, an active interlayer and a second semiconductor epitaxial layer, wherein the active interlayer is interposed between the first semiconductor epitaxial layer and the second semiconductor epitaxial layer.

4. The vertical light emitting diode as claimed in claim 3, wherein the first semiconductor epitaxial layer and the first electrode layer are each P type, and the second semiconductor epitaxial layer and the second electrode layer are each N type.

5. The vertical light emitting diode as claimed in claim 3, wherein the first electrode includes a first electrode layer and a reflective layer, wherein the reflective layer is interposed between the first electrode layer and the semiconductor epitaxial multilayer structure.

6. The vertical light emitting diode as claimed in claim 1, wherein the conductive DLC layer is a multilayer structure composed by a conductive material and a conductive DLC, a DLC layer including the conductive material, a graphitizing DLC layer or a combination thereof.

7. The vertical light emitting diode as claimed in claim 1, wherein the conductive substrate is composed of a metal, a ceramic including the conductive material or a diamond including the conductive material.

8. The vertical light emitting diode as claimed in claim 1, wherein the first passivation layer and the second passivation layer are each independently composed of silicon dioxide, silicon nitride, aluminum nitride, insulated DLC or a combination thereof.

9. A method of manufacturing a vertical light emitting diode, comprising:
providing a temporary substrate and forming a semiconductor epitaxial multilayer structure, a first electrode and a first passivation layer on the temporary substrate, wherein the semiconductor epitaxial multilayer structure is disposed on the temporary substrate, the first passivation layer and the first electrode are disposed on the semiconductor epitaxial multilayer structure, the first passivation layer is patterned into a first opening, and the first electrode is embedded in the first opening of the first passivation layer;
forming a conductive DLC layer on the first passivation layer and the first electrode;
patterning the semiconductor epitaxial multilayer structure to expose the first passivation layer;
forming a second passivation layer on the patterned semiconductor epitaxial multilayer structure and the first passivation layer, wherein a plurality of second openings is disposed on the second passivation layer to expose the patterned semiconductor epitaxial multilayer structure; and
forming a second electrode in the second openings of the second passivation layer and on the patterned semiconductor epitaxial multilayer structure.

10. The method as claimed in claim 9, wherein the first passivation layer is formed on the semiconductor epitaxial multilayer structure and then patterned to form the first opening, after that, on the semiconductor epitaxial multilayer structure, forming the first electrode in the first opening of the first passivation layer.

11. The method as claimed in claim 9, before forming the second passivation layer, further comprising:
roughening the patterned semiconductor epitaxial multilayer structure.

12. The method as claimed in claim 9, wherein the first electrode includes a first electrode layer and a reflective layer, wherein the reflective layer is interposed between the first electrode layer and the semiconductor epitaxial multilayer structure.

13. The method as claimed in claim 9, wherein the semiconductor epitaxial multilayer structure includes a first semiconductor epitaxial layer, an active interlayer and a second semiconductor epitaxial layer, wherein the active interlayer is interposed between the first semiconductor epitaxial layer and the second semiconductor epitaxial layer.

14. The vertical light emitting diode as claimed in claim 13, wherein the first semiconductor epitaxial layer and the first electrode layer are each P type, and the second semiconductor epitaxial layer and the second electrode layer are each N type.

15. The method as claimed in claim 13, wherein the first electrode includes a first electrode layer and a reflective layer and the reflective layer is interposed between the first electrode layer and the semiconductor epitaxial multilayer structure.

16. The method as claimed in claim 9, wherein the conductive DLC layer is a multilayer structure composed by a conductive material and a conductive DLC, a DLC layer including the conductive material, a graphitizing DLC layer or a combination thereof.

17. The method as claimed in claim 9, wherein the conductive substrate is composed of a metal, a ceramic including the conductive material or a diamond including the conductive material.

18. The method as claimed in claim 9, wherein the first passivation layer and the second passivation layer is independently composed of silicon dioxide, silicon nitride, aluminum nitride, insulated DLC or a combination thereof.

19. A chip on board (COB), comprising:
a print circuit board; and
a vertical light emitting diode as recited in claim 1 which is encapsulated in the print circuit board.

20. The COB as claimed in claim 19, wherein the print circuit board includes an insulated layer and a print circuit substrate, the insulated layer is at least one selected from the group consisting of diamond-like carbon, aluminum oxide, ceramic and an epoxy resin including diamond.

21. The COB as claimed in claim 20, wherein the print circuit substrate is a metal plate, a ceramic plate or a silicon substrate.
